(19) United States
(12) Patent Application Publication
(10) Pub. No.: US 2012/0091554 A1
(43) Pub. Date: Apr. 19, 2012

(54) SEMICONDUCTOR DEVICE AND METHOD FOR MANUFACTURING THE SAME

(75) Inventor: Sang Soo LEE, Yeoju-gun (KR)

(73) Assignee: Hynix Semiconductor Inc., Icheon-si (KR)

(21) Appl. No.: 12/982,600

(22) Filed: Dec. 30, 2010

(30) Foreign Application Priority Data
Oct. 15, 2010 (KR) 10-2010-0101076

(51) Int. Cl. H01L 23/58; H01L 21/762

(52) U.S. Cl. 257/510; 438/424; 257/E23.002; 257/E21.546; 257/E21.545

(57) ABSTRACT

A method for manufacturing a semiconductor device comprises: etching a semiconductor substrate to form a trench that defines an active region of a line type; burying an insulating film in the trench; and removing a portion of the active region of a line type to form a separated active region. The method improves the process for forming an active region using a Spacer patterning Technology (SPT), thereby preventing characteristic defects of the device and improving the operating characteristic.

### CROSS-REFERENCE TO RELATED APPLICATION

The priority of Korean patent application No. 10-2010-0101076 filed on Oct. 15, 2010, the disclosure of which is hereby incorporated in its entirety by reference, is claimed.

### BACKGROUND OF THE INVENTION

An embodiment of the present invention relates to a semiconductor device and a method for manufacturing the same, and more specifically, to a semiconductor device and a method for manufacturing the same that comprises forming an active region using a Spacer Patterning Technology (SPT).

Recently, since the research on methods for reducing a unit cell area has been made, a gap between active regions becomes closer in a DRAM device. Moreover, in a 6F2 structure of a DRAM cell, since the active regions have a fine interval therebetween, a space between the active regions becomes smaller. However, it is hard to form a fine pattern due to a resolution limit of an exposure. In order to overcome this problem, a line pattern is formed by a SPT. These line patterns are separated with a cutting mask, thereby obtaining the active region.

FIGS. 1a to 1c are diagrams illustrating a conventional semiconductor device and a method for manufacturing the same. FIG. 1a (i) to FIG. 1c (i) illustrate plan views of a cell region and a peripheral circuit region, and FIG. 1a (ii) to FIG. 1c (ii) illustrate cross-sectional views taken along I-I′ of FIG. 1a (i) to FIG. 1c (i).

Referring to FIG. 1a, a pad insulating film 15 and a hard mask pattern 20 of a line type are formed over a semiconductor substrate 10 of a cell region. A Spacer Patterning Technology (SPT) process is performed to form the hard mask pattern 20 so that the hard mask pattern 20 may have a fine line-width smaller than a critical dimension (a resolution size limit) of an employed photolithography process. As shown in FIG. 1b, a photoresist film (not shown) is formed over the semiconductor substrate 10 including the first hard mask pattern 20. Thereafter, a photoresist pattern (not shown) that exposes a portion of the first hard mask pattern 20 is formed using a cutting mask having a hole type pattern. The first hard mask pattern 20 in the cell region is etched using the cutting mask to form a second hard mask pattern 20a as a hole type that defines an active region. The first hard mask pattern 20 in the peripheral circuit region is etched using the cutting mask to form the second hard mask pattern 20a that defines the active region as a pad type.

Referring to FIG. 1c, the pad insulating film 15 and the semiconductor substrate 10 of the cell region and the peripheral circuit region are etched with the second hard mask pattern 20a as an etching mask to form a trench for device isolation that defines an active region 10a. An insulating material is buried in the trench for device isolation, thereby forming a device isolation film 25. In the etching process for forming the trench for device isolation, the semiconductor substrate 10 is etched in the cell region so that the edges of the active region are rounded and thus a line-width of the major axis of the active region is reduced. Also, while the semiconductor substrate of the cell region is etched, because of a concern that the active region may collapse, the depth of the cell region cannot be formed sufficiently deep, thereby increasing leakage current between cells.

Moreover, as an effective area of the active region is reduced, the thickness of a sidewall oxide film in the active region becomes one of important factors causing a loss in an effective size of the active region. Thus, the sidewall oxide film needs to be formed thinly. However, when the sidewall oxide film is deposited thinly, a Hot Electron Induced Punch-through (HEIP) characteristic of a transistor formed in the peri region is degraded.

### BRIEF SUMMARY OF THE INVENTION

Various embodiments of the invention are directed to improving a process for forming an active region using a Spacer Patterning Technology (SPT), thereby preventing characteristic defects of the device and improving the operating characteristics.

According to an embodiment of the present invention, a method for manufacturing a semiconductor device comprises: etching a semiconductor substrate to form a trench that defines an active region of a line type; burying an insulating film in the trench; and removing a portion of the active region of a line type to form a separated active region.

The forming-a-trench includes: forming a mask pattern of a line type over the semiconductor substrate; and etching the semiconductor substrate by using the mask pattern as an etch mask.

The mask pattern is formed by a Spacer Patterning Technology (SPT) process.

The method further comprises forming a sidewall oxide film over the inner wall of the trench.

The insulating film includes a fluid insulating material.

According to another embodiment of the present invention, a method for manufacturing a semiconductor device comprises: etching a semiconductor substrate in a cell region to form a first trench that defines a line type active region; providing a first insulating film in the first trench to form a active region; removing a portion the line type active region in the cell region to form a first active region separated from the active region and etching the semiconductor substrate in a peripheral circuit region to form a second trench that defines a second active region; and burying a second insulating film in the second trench in a portion where the active region is removed.

The forming the first trench includes: forming a mask pattern of a line type over the semiconductor substrate in the cell region; and etching the semiconductor substrate using the mask pattern as an etch mask.

The mask pattern includes any of an amorphous carbon layer, a silicon oxide nitride film, a polysilicon layer or a combination thereof.

The method further comprises forming a sidewall oxide film over an inner wall of the first trench.

The first insulating film and the second insulating film include fluid insulating material.

The forming a first active region includes: forming a mask pattern that exposes a portion of the active region over the semiconductor substrate including the first insulating film and the active region of a line type; and removing the exposed portion of the active region by using the mask pattern as an etch mask.

The mask pattern is a hole type pattern formed to expose the first active region in each given interval.

The forming a second trench includes: forming a pad type mask pattern that defines a second active region over the semiconductor substrate in the peripheral circuit region; and etching the semiconductor substrate by using the mask pattern as an etch mask.

The method further comprises forming a sidewall oxide film over the inner wall of the second trench.

The sidewall oxide film formed over the inner wall of the second trench is formed 2˜3 times thicker than the sidewall oxide film formed over the inner wall of the first trench.

The forming the first active region is simultaneously performed with forming the second trench.

According to an embodiment of the present invention, a semiconductor device comprises: a first device isolation film disposed in a cell region to define a first active region which has the same line width as that of the center part and the edge of both sides; and a second device isolation film disposed in a peripheral circuit region to define a second active region.

The first active region is a bar type rectangular and the second active region has a pad type.

The semiconductor device further comprises a sidewall oxide film over the inner sides of the first device isolation film and the second device isolation film or both.

The sidewall oxide film included over the inner side of the second device isolation film is formed 2˜3 times thicker than the sidewall oxide film formed over the inner side of the first device isolation film.

According to an embodiment of the present invention, a method for manufacturing a semiconductor device, the method comprising: forming a first line mask pattern in a cell region of a substrate; patterning the substrate using the first line mask pattern to form first and second trenches at first and second sides of the first line mask pattern; providing insulating material into the first and the second trenches to form first and second device isolation patterns, respectively; and patterning the first line mask pattern to form a third trench extending through the first line mask pattern and connecting the first and the second device isolation patterns, providing insulating material into the third trench to form a third device isolation pattern, wherein the patterned first line mask pattern defines an active region, and wherein the first, the second and the third device insulating patterns in combination define a device isolation region.

### BRIEF DESCRIPTION OF THE DRAWINGS

FIGS. 1a to 1c are diagrams illustrating a conventional semiconductor device and a conventional method for manufacturing the same.

FIGS. 2a to 2g are diagrams illustrating a semiconductor device and a method for manufacturing the same according to an embodiment of the present invention.

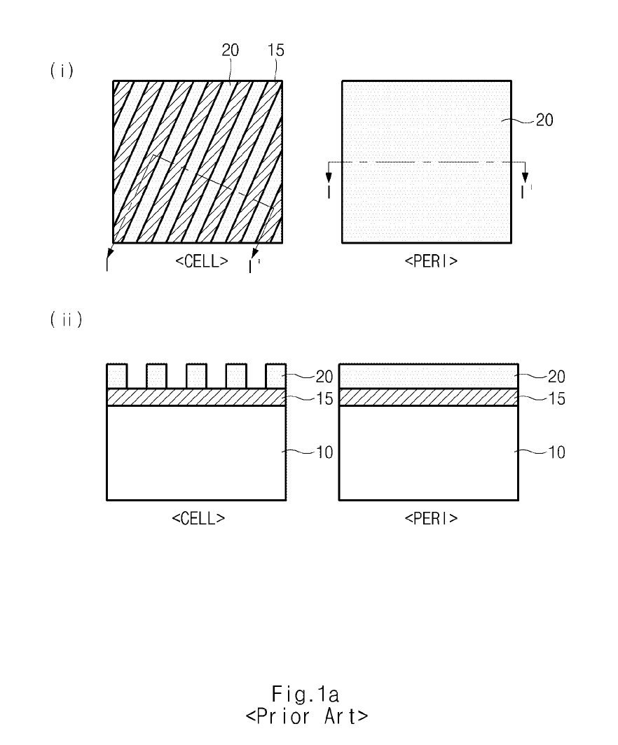

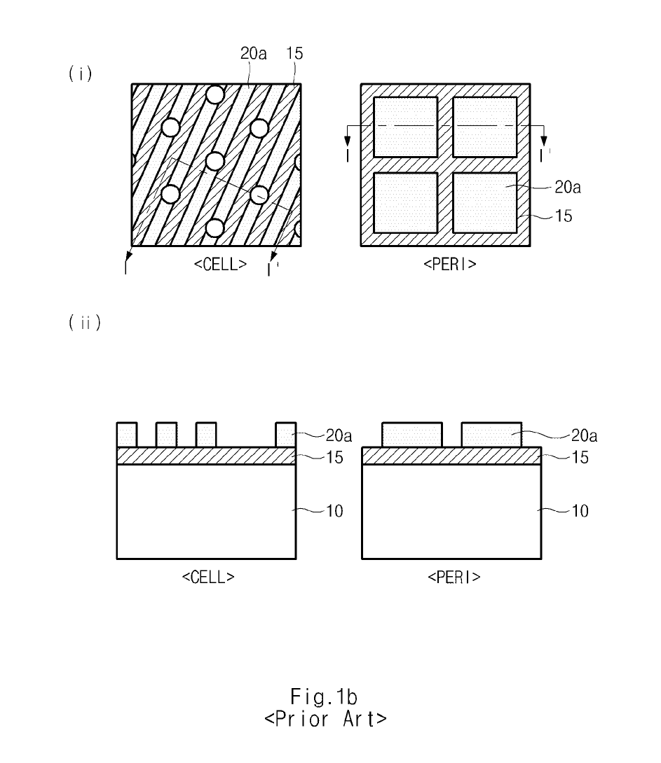

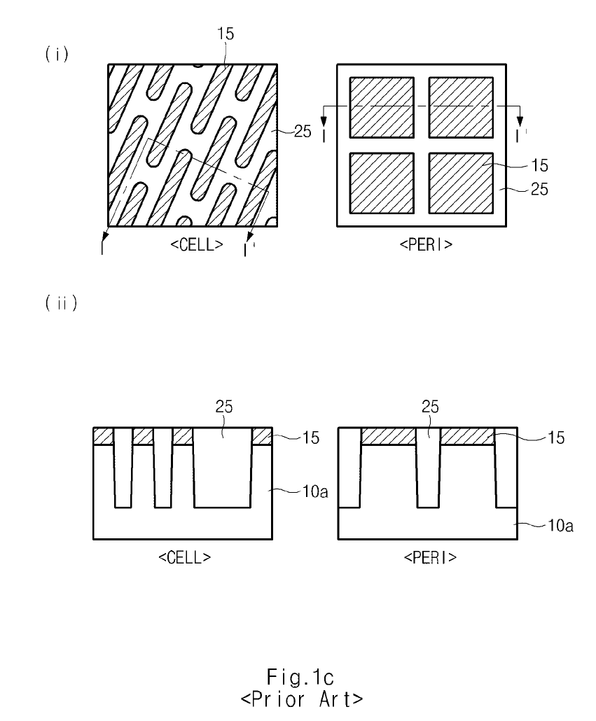

### DESCRIPTION OF EMBODIMENTS

The present invention will be described in detail with reference to the attached drawings.

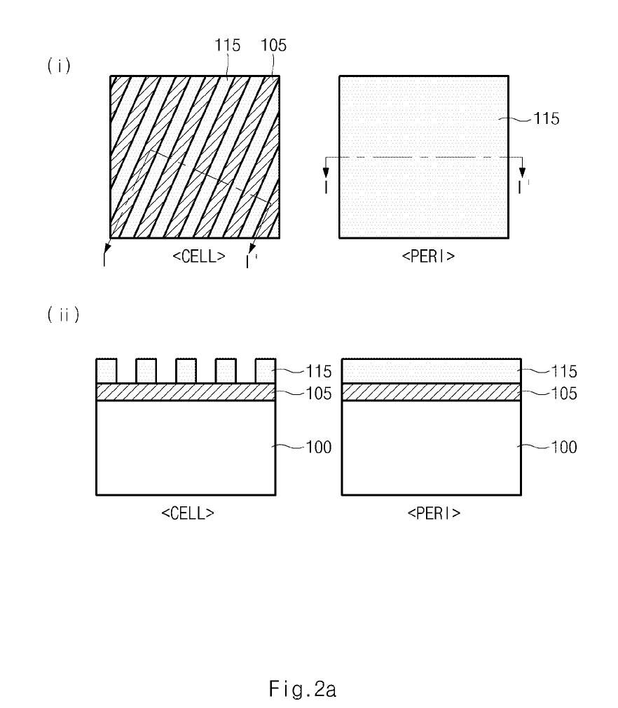

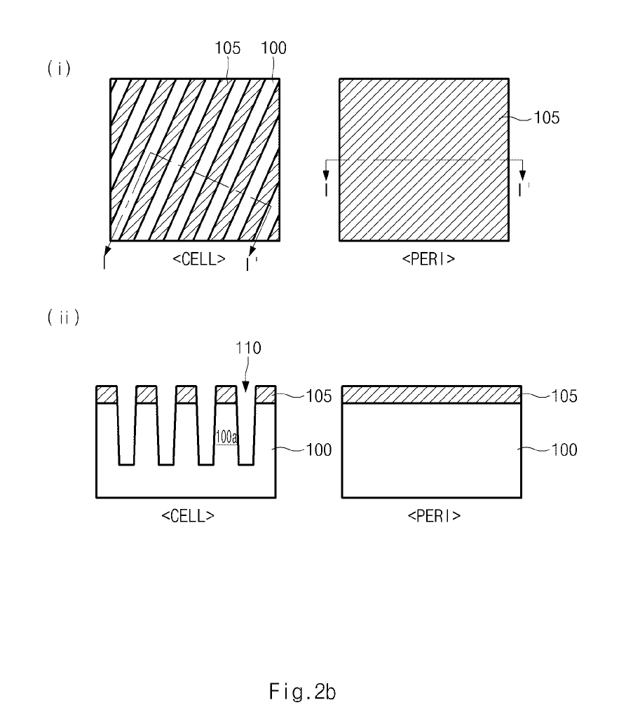

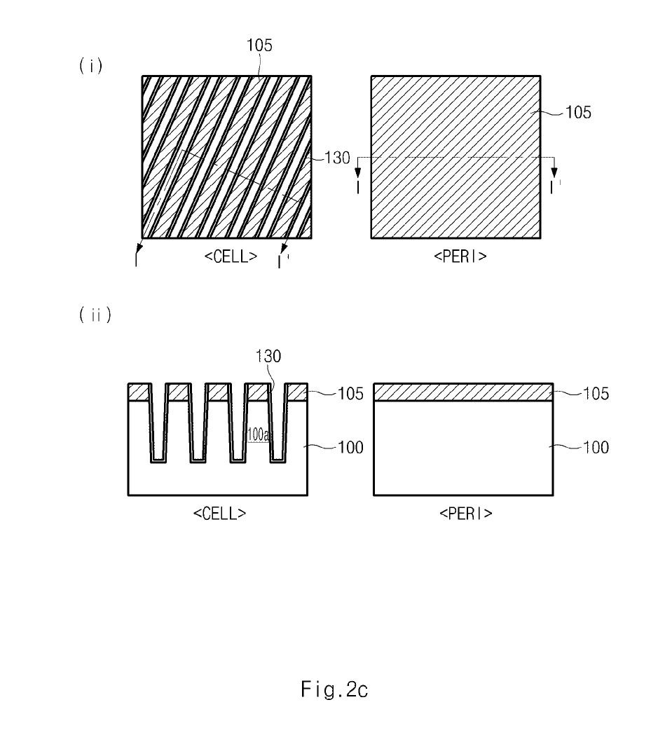

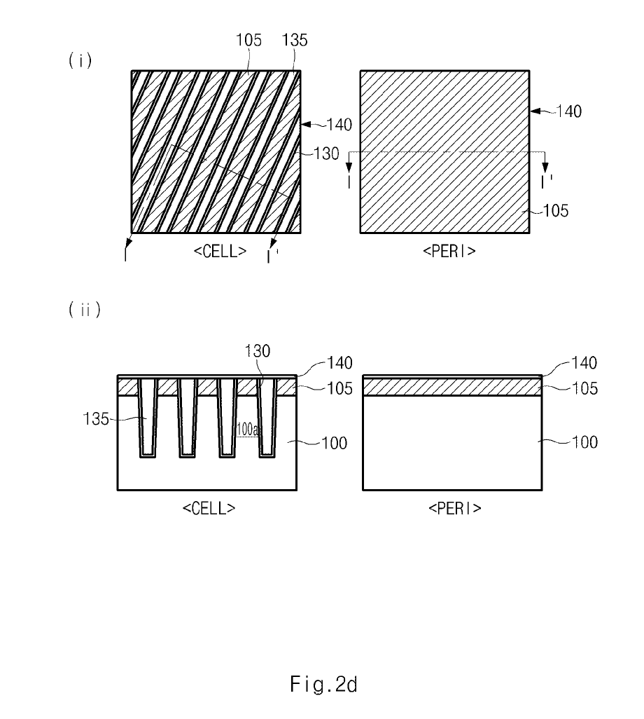

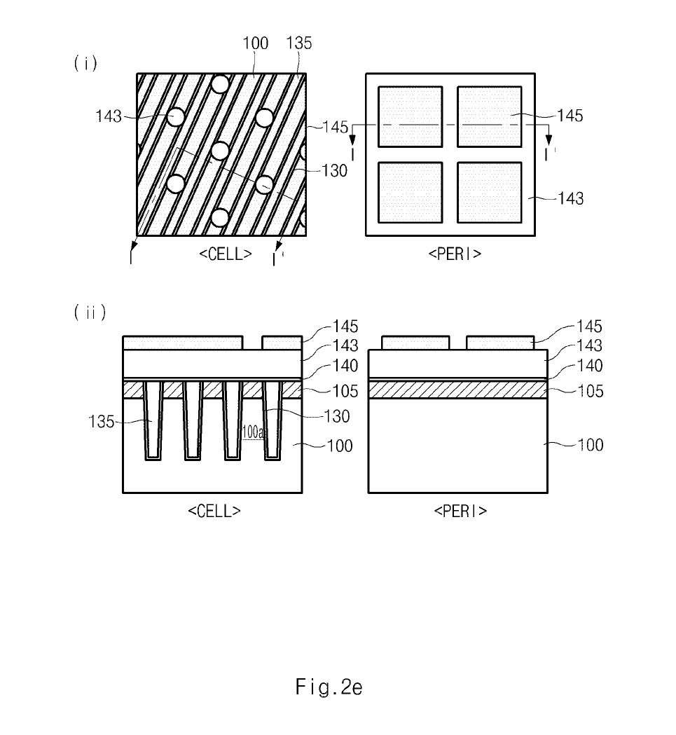

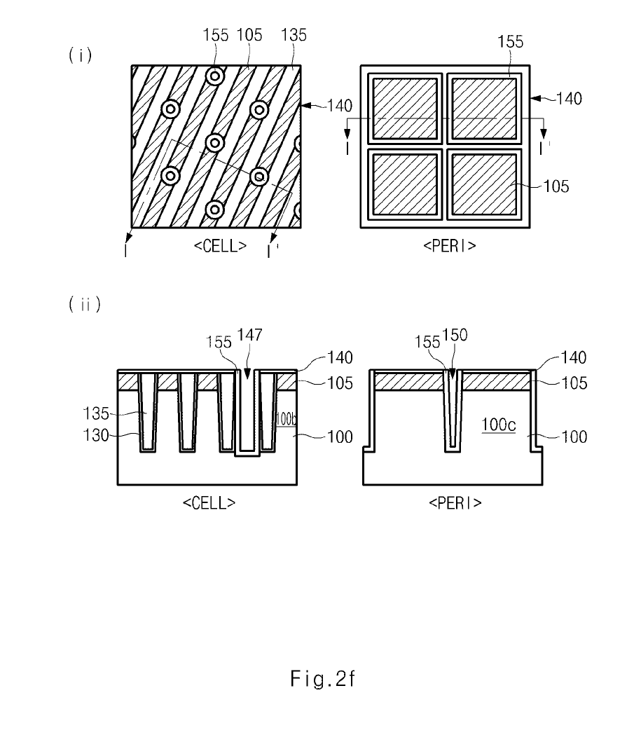

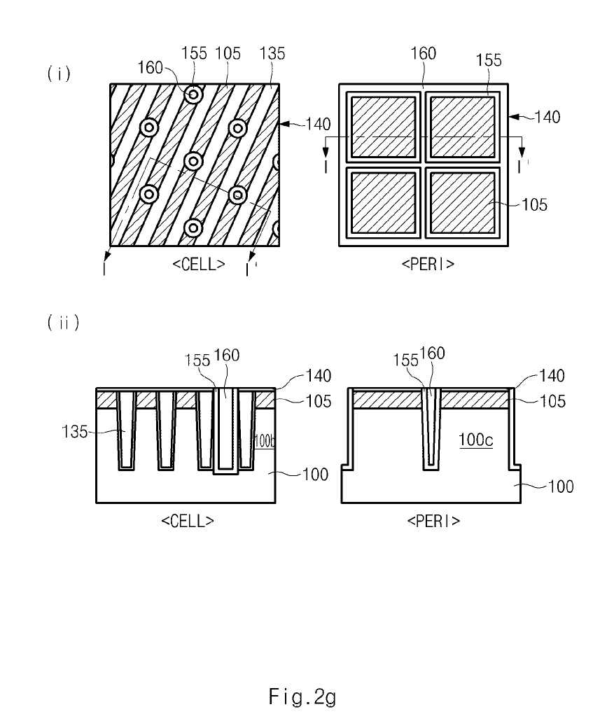

FIGS. 2a to 2g are diagrams illustrating a semiconductor device and a method for manufacturing the same according to an embodiment of the present invention. FIG. 2a (i) to FIG. 2g (i) illustrate plan views of a cell region and a peripheral circuit region, and FIG. 2a (ii) to FIG. 2g (ii) illustrate cross-sectional views taken along I-I′ of FIG. 2a (i) to FIG. 2g (i).

Referring to FIG. 2a, a pad insulating film 105 and a hard mask layer are formed over a semiconductor substrate 100 of the cell region and the peripheral region. The pad insulating film 105 is formed with a material including a nitride film. The hard mask layer includes any of an amorphous carbon layer, a silicon oxide nitride (SiON) film, polysilicon, or a combination thereof.

The hard mask layer of the cell region is etched to form a first hard mask pattern 115 of a line type. A SPT process is performed to form the first hard mask pattern 115 having a fine line-width. More specifically, after a sacrificial pattern (not shown) of a line type is formed over a hard mask layer (not shown), spacers (not shown) are formed at both sidewalls of the sacrificial pattern (not shown). The sacrificial pattern (not shown) is removed while leaving the spacer (not shown). Thereafter, the hard mask layer (not shown) is etched with the spacer (not shown) as an etching mask to obtain the first hard mask pattern 115. As shown in FIG. 2a, the first hard mask pattern 115 having a fine pattern is formed only in the cell region. The hard mask layer in the peripheral circuit region is not etched.

In general, since a 6F2 (F denotes a critical dimension, i.e., a minimum line pattern size obtainable under a given photolithography system) structure reduces the size of an active region, the active region is arranged at an angle with respect to a bit line and a word line in order to increase the active region size as much as possible. As a result, the first hard mask pattern 115 is also arranged at a given angle with respect to a word line (not shown) and a bit line (not shown), as shown in FIG. 2a (i). However, the arrangement of the first hard mask pattern 115 is not limited herein.

Referring to FIG. 2b, the pad insulating film 105 of FIG. 2a and the semiconductor substrate 100 are etched by using the first hard mask pattern 115 as an etching mask to form a first trench 110 that defines an active region 100a. In order to define an active region in the conventional art, a cutting process for cutting the first hard mask pattern 115 of a line type and a patterning process for defining an active region in the peripheral circuit region are additionally performed. However, the first trench 110 is formed using the first hard mask pattern 115 of a line type, and then the first hard mask pattern 115 (see FIG. 2a) is removed.

In this way, since the process for cutting the first hard mask pattern 115 is not applied in the present invention, the active region is not yet defined at this stage. As a result, the supporting force of the active region 100a is strengthened to prevent the active region 100a from being collapsed. Thus, a trench for device isolation may be formed sufficiently deep without a concern that the active region 100a is may collapse, thereby reducing leakage current between cells.

Referring to FIG. 2c, a first sidewall oxide film 130 is formed on the surface of the etched pad insulating film 105 and the first trench 110 of the cell region. An oxidation process is performed to obtain the first sidewall oxide film 130. The first sidewall oxide film 130 is formed only in the cell region, and the first sidewall oxide film 130 is deposited as thin as possible in order to maximize the size of the active region 100a. The preferable thickness of the first sidewall oxide film 130 ranges from 30 to 40 Å. If necessary, a liner nitride film (not shown) and a liner oxide film (not shown) may be additionally deposited over the first sidewall oxide film 130.

Referring to FIG. 2d, an insulating film 135 is formed over the semiconductor substrate 100 including the first trench 110. The insulating film 135 includes a fluid insulating material with good step coverage. For example, the insulating film 135 is formed with a Spin On Dielectric (SOD) material. Thereafter, a thermal treatment process is formed for hardening the insulating film 135. Then, a Chemical Mechanical Polishing (CMP) process is performed to expose the pad insulating film 105 so that the hardened insulating film 135 is buried in the first trench 110. A capping film 140 is formed over the pad insulating film 105 and the insulating film 135. The capping film 140 includes a nitride film in order to prevent permeation of oxygen into the semiconductor substrate 100. If the capping film 140 is formed too thickly, it is difficult to perform a subsequent process for etching the trench for device isolation in the peripheral circuit region. As a result, the capping film 140 is formed to have a minimum thickness capable of preventing oxygen permeation. The preferable thickness of the capping film 140 ranges from 30 to 70 Å.

Referring to FIG. 2e, a second hard mask layer 143 is formed over the capping film 140. Like the first hard mask layer 115, the second hard mask layer 143 includes any of an amorphous carbon layer, a silicon oxide nitride film, polysilicon and a combination thereof. Thereafter, a photoresist film is formed over the second hard mask layer 143. An exposing and developing process is performed using an exposure mask defining the active region so that the active region 100a of the cell region and defining the active region 100a in the peripheral circuit region, thereby forming a photoresist pattern 145. In the cell region, the active region 100a of a line type is located under a transparent pattern region of the exposure mask pattern which is in a hole type. In the peripheral circuit region, a pad type transparent pattern is located over the active region of the peripheral circuit region. That is, as shown in FIG. 2e (i), the photoresist pattern 145 in a hole type is formed so that the active region 100a in a line type in the cell region is formed with a given interval. The phoeoresist pattern 145 serves as a cutting mask for patterning the active region 100a in a line type. The photoresist pattern 145 exposes a device isolation region. In the peripheral circuit region, the photoresist pattern 145 is formed in a pad type.

Referring to FIG. 2f, the second hard mask layer 143, the capping film 140, the pad insulating film 105 and the active region 100a are etched by using the photoresist pattern 145 of the cell region as an etching mask, thereby forming a second trench 147 that defines a first active region 100b. The semiconductor substrate 100 is etched by using the photoresist pattern 145 of the peripheral circuit region as an etching mask, thereby forming a second trench 150 that defines a second active region 100c. The etching process performed with the photoresist pattern 145 as an etching mask is performed with a CD bias and an etch depth of the peripheral circuit region as a target. In the cell region, a part where the hardened insulating film 135 is buried is etched with a simple hole type, thereby preventing a phenomenon of rounding or etching the end of the major axis of the active region in the conventional art.

Since the second trench 147 in the cell region is formed while being protected by the capping film 140 and the insulating film 135, a rounding phenomenon at the corner of the active region does not occur, and thus the effective area of the active region can be maximized. As a result, an overlap margin is improved in a subsequent process for forming a landing plug contact or a storage node contact, thereby improving cell performance. In the conventional art, since a gap between active regions in the cell region is narrower than that in the peripheral region, the etch depth in peripheral circuit region is formed deeper than that of the cell region. For example, when the cell region is etched by 100 Å, the peripheral circuit region is etched by a depth ranging from 200 to 300 Å, thereby increasing IDD and lowering overlay accuracy to generate a warpage problem. However, as shown in FIG. 2f, it is possible to adjust an etch target of the peripheral circuit region because separately the peripheral circuit region is etched.

A second sidewall oxide film (not shown) is formed in the second trench 150 of the peripheral circuit region. The second sidewall oxide film (not shown) is thickly formed in order to improve a Hot Electron Induced Punch-through (HEIP) characteristic. More specifically, the second sidewall oxide film (not shown) is formed to be thicker by 2˜3 times than the first sidewall oxide film 130 formed in the cell region. For example, the second sidewall oxide film (not shown) is formed at a thickness ranging from 60 to 100 Å. The second sidewall oxide film (not shown) may be deposited not only over the second trench 150 in the peripheral circuit region but also over the second trench 147 in the cell region. However, the upper portion of the first active region 100b of the cell region is covered by the capping film 140, thereby preventing the first active region 100b of the cell region from being damaged.

In the process for individually forming the sidewall oxide films in the cell region and the peripheral circuit region, a liner nitride film may not be formed in the peripheral circuit region even though a liner nitride film is formed in the cell region. When the liner nitride film is not formed in the peripheral circuit region, a well Breakdown Voltage (BV) and a junction BV can be improved. Also, a upper portion of the liner nitride film is removed and a threshold voltage of the peripheral circuit region can be prevented from being deteriorated.

Referring to FIG. 2g, second insulating films 160 are formed over the inner surface of the second trench 147 of the cell region and the second trench 150 of the peripheral circuit region. Thereafter, a process for hardening the second insulating film 160 is performed. A CMP process is performed until the capping film 140 is exposed, thereby forming a final active region and a device isolation film.

As described above, if the process of etching the substrate is performed without any cutting process after the SPT process, the patterns are all connected so that the supporting force becomes stronger, thereby preventing collapse of the patterns. As a result, the cell region can be etched deeply, thereby preventing leakage current generated between cells.

In addition, the etch depth and the line-width of the peripheral circuit region can be regulated independently from those of the cell region. Since the sidewall oxide film is thickly formed only in the peripheral circuit region, the HEIP characteristic can be improved. Furthermore, the insulating film is filled in the second trench 147 in the cell region and is subjected to the thermal treatment, and no rounding phenomenon occurs in the active region, thereby increasing the effective area of the active region. As a result, the resistance characteristic of the cell region is improved.

The above embodiments of the present invention are illustrative and not limitative. Various alternatives and equivalents are possible. The invention is not limited by the type of deposition, etching polishing, and patterning steps describe herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A method for manufacturing a semiconductor device, the method comprising:
etching a semiconductor substrate to form a trench that defines a line type active region;
providing an insulating film in the trench; and
removing a portion of the line type active region to form a separated active region.

2. The method according to claim 1, wherein forming the trench includes:
forming a mask pattern of a line type over the semiconductor substrate; and
etching the semiconductor substrate by using the mask pattern as an etch mask.

3. The method according to claim 2, wherein the mask pattern is formed by a Spacer Patterning Technology (SPT) process.

4. The method according to claim 1, further comprising forming a sidewall oxide film over an inner wall of the trench.

5. The method according to claim 1, wherein the insulating film includes a fluid insulating material.

6. A method for manufacturing a semiconductor device, the method comprising:
etching a semiconductor substrate in a cell region to form a first trench that defines an active region of a line type;
forming a first insulating film in the first trench to form an active region;
removing a portion of the active region in the cell region to form a first active region separated from the active region;
etching the semiconductor substrate in a peripheral circuit region to form a second trench that defines a second active region; and
forming a second insulating film in the second trench in a portion where the active region is removed.

7. The method according to claim 6, wherein forming the first trench includes:
forming a mask pattern of a line type over the semiconductor substrate in the cell region; and
etching the semiconductor substrate using the mask pattern as an etch mask.

8. The method according to claim 7, wherein the mask pattern includes any of an amorphous carbon layer, a silicon oxide nitride film, a polysilicon layer or a combination thereof.

9. The method according to claim 6, further comprising forming a sidewall oxide film over an inner wall of the first trench.

10. The method according to claim 6, wherein the first insulating film and the second insulating film include fluid insulating material.

11. The method according to claim 6, wherein the forming-a-first-active region includes:
forming a mask pattern that exposes a portion of the active region over the semiconductor substrate including the first insulating film and the active region of a line type; and
removing the exposed portion of the active region by using the mask pattern as an etch mask.

12. The method according to claim 11, wherein the mask pattern is a hole type pattern formed to expose the first active region in each given interval.

13. The method according to claim 6, wherein forming the second trench includes:
forming a pad type mask pattern that defines a second active region over the semiconductor substrate in the peripheral circuit region; and
etching the semiconductor substrate using the mask pattern as an etch mask.

14. The method according to claim 9, further comprising forming a sidewall oxide film over the inner wall of the second trench.

15. The method according to claim 14, wherein the sidewall oxide film formed over the inner wall of the second trench is formed 2˜3 times thicker than the sidewall oxide film formed over the inner wall of the first trench.

16. The method according to claim 6, wherein forming the first active region is simultaneously performed with forming the second trench.

17. A semiconductor device comprising:
a first device isolation film disposed in a cell region to define a first active region which has the same line width as that of the center part and the edge of both sides; and
a second device isolation film disposed in a peripheral circuit region to define a second active region.

18. The semiconductor device according to claim 17, wherein the first active region is a bar type rectangular and the second active region is a pad type.

19. The semiconductor device according to claim 17, further comprising a sidewall oxide film over the inner sides of the first device isolation film, the second device isolation film or both.

20. The semiconductor device according to claim 19, wherein the sidewall oxide film included over the inner side of the second device isolation film is formed 2˜3 times thicker than the sidewall oxide film formed over the inner side of the first device isolation film.

21. A method for manufacturing a semiconductor device, the method comprising:
forming a first line mask pattern in a cell region of a substrate;
patterning the substrate using the first line mask pattern to form first and second trenches at first and second sides of the first line mask pattern;
providing insulating material into the first and the second trenches to form first and second device isolation patterns, respectively; and
patterning the first line mask pattern to form a third trench extending through the first line mask pattern and connecting the first and the second device isolation patterns,
providing insulating material into the third trench to form a third device isolation pattern,
wherein the patterned first line mask pattern defines an active region, and
wherein the first, the second and the third device insulating patterns in combination define a device isolation region.
